(19) United States
(12) Patent Application Publication
(10) Pub. No.: US 2025/0379032 A1
(43) Pub. Date: Dec. 11, 2025

(54) METAL-OXIDE VARISTOR (MOV) BASED SURGE PROTECTION CIRCUIT FOR PLASMA PROCESSING CHAMBER

(71) Applicant: Lam Research Corporation, Fremont, CA (US)

(72) Inventors: Ali FROTANPOUR, Tualatin, OR (US); Thomas Lee FREDERICK, West Linn, OR (US)

(73) Assignee: Lam Research Corporation, Fremont, CA (US)

(21) Appl. No.: 18/874,526

(22) PCT Filed: May 31, 2023
(86) PCT No.: PCT/US2023/024052

§ 371 Date: Dec. 12, 2024

Related U.S. Application Data
(60) Provisional application No. 63/368,472, filed on Jul. 14, 2022.

(51) Int. Cl. H01J 37/32

(52) U.S. Cl. CPC H01J 37/32174; H01J 37/32944

(57) ABSTRACT

A system includes a chamber configured to produce and contain a plasma. The system includes a transmission line positioned in the chamber. The transmission line includes a transmission line input and includes an output coupled to a common potential. The system includes a signal source coupled to the transmission line input to feed an input signal to the transmission line. The system includes a surge protection circuit coupled between the transmission line input and the common potential. An impedance of the surge protection circuit is inversely related to a voltage level at the transmission line input.

### CLAIM FOR PRIORITY

This application claims priority to U.S. Provisional Patent Application No. 63/368,472, filed on Jul. 14, 2022, titled “METAL-OXIDE VARISTOR (MOV) BASED SURGE PROTECTION CIRCUIT FOR PLASMA PROCESSING CHAMBER,” and which is incorporated by reference in entirety.

### BACKGROUND

Plasma deposition is a process utilized to deposit thin films on a substrate using a plasma source. The plasma may be created in a chamber which includes a transmission line. A signal source feeds a radio frequency (RF) signal or a direct current (DC) to the transmission line. By changing electrical parameters such as the frequency and voltage of the signal fed into the transmission line, a spatial distribution and an ion energy of the plasma is modulated. The plasma deposition process can be controlled by modulating the spatial distribution and ion energy of the plasma.

During a plasma deposition process, a voltage spike or surge may occur in the chamber due to “arcing” or due to a change in the load (e.g., semiconductor wafer or substrate). The voltage spike or surge may be a transient event, typically lasting few nanoseconds to 30 microseconds, that may reach, for example, 1000V, 2000V, or 3000V. The voltage spike or surge may be coupled to the signal source, thereby damaging the signal source.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a system, in accordance with at least one implementation.

FIG. 2 illustrates a system that includes an implementation of a surge protection circuit, in accordance with at least one implementation.

FIG. 3 illustrates a system in which a surge protection circuit is implemented with a passive RLC circuit, in accordance with at least one implementation.

FIG. 4A illustrates a plot of a resistance of a metal-oxide varistor (MOV) at lower frequencies; FIG. 4B illustrates a plot of a reactance of the MOV at lower frequencies; and FIG. 4C illustrates a plot of a capacitance of the MOV as a function of a voltage, in accordance with at least one implementation.

FIG. 5 illustrates a plot of an impedance of a surge protection circuit as a function of a voltage, in accordance with at least one implementation.

FIG. 6 illustrates plots of an impedance of a surge protection circuit as a function of a frequency as a capacitance of an MOV varies, in accordance with at least one implementation.

FIG. 7 illustrates a system of an example implementation that includes an implementation of an over-voltage detection circuit, in accordance with at least one implementation.

### DETAILED DESCRIPTION

A metal-oxide varistor (MOV) based surge protection circuit for a plasma processing chamber is described in accordance with at least one implementation. In the following description, numerous specific details are set forth, such as structural schemes to provide a thorough understanding of implementations of the present disclosure. It will be apparent to one skilled in the art that implementations of the present disclosure may be practiced without these specific details. In other instances, well-known features are described in lesser detail to not unnecessarily obscure implementations of the present disclosure. Furthermore, it is to be understood that the various implementations shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an implementation” or “one implementation” or “some implementations” means that a particular feature, structure, function, or characteristic described in connection with the implementation is included in at least one implementation of the disclosure. Thus, the appearances of the phrase “in an implementation” or “in one implementation” or “some implementations” in various places throughout this specification are not necessarily referring to the same implementation of the disclosure. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.

Here, “coupled” and “connected,” along with their derivatives, may be used herein to describe functional or structural relationships between components. These terms are not intended as synonyms for each other. Rather, in particular implementations, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship). The term “coupled” may generally refer to direct or indirect attachment of one electronic component to another. An electric or magnetic field may couple one component to another, where the field is controlled by one component to influence the other in some manner.

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In at least one implementation, such variation is typically no more than +/−10% of the referred value.

Here, “transmission line” may generally refer to a plurality of conductive elements or segments electrically coupled. In at least one implementation, transmission lines may be built using discrete elements (e.g., inductors, capacitors). In at least one implementation, an individual wire of a transmission line may be represented by an inductance L shunted by a distributed capacitance C per unit length, where the distributed capacitance is proportional to the dielectric constant of the dielectric material between the conductors.

Here, “terminal” may generally refer to the end of a conductor or electrical component, such as a wire, which may be a point of connection for other conductors or electrical components. In at least one implementation, in the context of a coil, the terminal is the end of a winding. Referring to coil segments, in at least one implementation, the coil segment may comprise a terminal at the beginning and the end of a coil segment conductor.

Here, “inductor” may generally refer to passive electrical device that stores magnetic energy from an electrical current flowing through it. In at least one implementation, an inductor may comprise a conductor (e.g., a metal wire) that may couple an electrically generated magnetic field into another conductor that is nearby, inducing a voltage and current in the second conductor. In at least one implementation, magnetic field may be generated by currents flowing within the first conductor according to Faraday's law of induction. In at least one implementation, conductors have the property of inductance, which is a function of the magnitude of the current flowing within the conductor and the shape or geometry of the conductor. In at least one implementation, while any conductor may be an inductor, some shapes produce a stronger inductance than others. In at least one implementation, a straight wire may have a small inductance that is dependent on its diameter and length. In at least one implementation, straight wire may be wound into a coil to multiply the inductance by the number of windings per unit length, for example, due to mutual additive coupling of magnetic fields between each winding, reinforcing the overall magnetic field. In at least one implementation, magnetic fields from each winding couple, produce a multiplication of the magnetic field produced by the straight wire according to Ampere's law. In at least one implementation, coil may be a planar coil, or a helical coil, such as a solenoid or tapered helix.

Here, “capacitor” may generally refer to a passive electrical device that stores electrical charge and electrical energy in the form of an electric field. In at least one implementation, a capacitor generally has at least two conductive plates in proximity to one another, separated by a dielectric material. In at least one implementation, dielectric material may be air (or other gas) or vacuum. In at least one implementation, dielectric may generally be a solid or liquid material, such as a polymer, a ceramic, or a semi-liquid electrolyte. In at least one implementation, opposite electrical charges may accumulate on the adjacent plates, forming an electric field extending from plate to plate through the dielectric. In at least one implementation, electric field can store electrical energy.

Here, “plasma” may generally refer to a gaseous formation comprising charged particles, such as positively or negatively charged atomic or molecular ions and electrons. In at least one implementation, plasmas are considered the fourth state of matter.

Here, “modulate” may generally refer to vary or to adjust, and the term “modulate plasma” may generally refer to vary a spatial distribution and ion energy of the plasma.

Here, “rectifier” may generally refer to an electronic circuit that converts alternating current (AC), which periodically reverses direction, to direct current (DC), which flows in only one direction.

Here, “tank circuit” may generally refer to a parallel combination of an inductor and a capacitor. In at least one implementation, tank circuit has a characteristic resonant frequency f0 that is determined by the values of inductance L and capacitance C, where f0=1/[2pΠLC]. In at least one implementation, a tank circuit has a resonance curve that is a plot of circuit impedance as a function of frequency. In at least one implementation, curve is non-monotonic in that it has a peak at the resonant frequency. In at least one implementation, sharpness and bandwidth of the resonance curve is determined by the quality factor Q of the circuit. Q may be defined as the ratio of energy stored in the electric field and magnetic field of the capacitor and inductor, respectively, to the energy dissipated as heat by resistive parts of the circuit. In at least one implementation, resistance may mostly be in the inductor (e.g., as copper loss, skin effect), as it may comprise a long piece of thin wire wound into a coil. In at least one implementation, smaller the resistance of the coil, the larger the Q. The Q may be lowered by insertion of a discrete resistor in series with the inductor in the tank circuit. In at least one implementation, resonance curve may be broadened by a low circuit Q (e.g., Q<10), and sharpened by a high circuit Q (e.g., Q>10). In at least one implementation, tank circuits exhibit very large circulating currents at or near resonance. In at least one implementation, circulating current may be the product of the line, or feed current, multiplied by the Q. Very large voltages may also appear across the capacitor and inductor because of the large circulating current. At the same time, in at least one implementation, impedance of the tank circuit increases dramatically at or near resonance and becomes purely resistive at f0. In at least one implementation, resonant tank circuits can have a very high effective resistance that severely reduces conduction of the RF current at f0. Here, “tank” circuit is derived from the circuit's ability to store electrical energy. In at least one implementation, tank circuits are uses as frequency-determining components of oscillator circuits and tuned coupling circuits, such as found in tuned RF amplifier stages.

Here, “dielectric material” may generally refer to a non-electrically conductive material, such as a polymer, a ceramic, glass, wood, etc.

Here, “radio frequency” may generally refer to electromagnetic radiation that oscillates at frequencies in a spectrum that is substantially inclusive of frequencies between 10 kilohertz (kHz) and 1 terahertz (THz, or 1015 Hz). In at least one implementation, upper limit of the radio frequency spectrum may extend only to several hundred gigahertz (GHz). Radio frequency as a term is commonly abbreviated to “RF”.

Here, “signal source” may generally refer to an electronic device that can generate electrical signals at radio frequency or another desired frequency. In at least one implementation, signal source is capable of outputting significant current (e.g., 1 ampere rms or greater) at significant voltages.

Here, “passive RLC circuit” may generally refer to an electrical circuit consisting of a resistor (R), an inductor (L), and a capacitor (C), connected in series or in parallel. In at least one implementation, passive RLC circuit forms an oscillator for current, and resonates at a resonant frequency. In at least one implementation, resistor increases the decay of the oscillation, which is known as damping.

Here, “chuck” may generally refer to a stage or platform on which a substrate (e.g., a wafer) may be attached.

Here, “electrostatic chuck” may generally refer to a platform which may include an electrode plate and an insulator disposed on the electrode plate.

Here, the term “substrate” may generally refer to a wafer comprising a semiconductor (e.g., silicon) or an insulator (e.g., aluminum nitride, silicon carbide, silicon nitride, aluminum oxide, float glass, borosilicate glass, etc.). In at least one implementation, a wafer may be a slice of monocrystalline semiconductor or insulator. In at least one implementation, a wafer may also comprise a polycrystalline or an amorphous (glassy) material. In at least one implementation, wafer may have a diameter generally ranging between 100 mm to 500 mm, and a thickness generally ranging between 100 microns and 1 mm.

Here, “chamber” may generally refer to a vacuum chamber of a process tool into which a substrate may be introduced for processing. In at least one implementation, chamber may include a chuck for holding the substrate. In at least one implementation, a process chamber is a plasma etch chamber.

Here, “spatial control” may generally refer to positional control of a process. In at least one implementation, spatial control of a plasma etch or deposition by providing spatially resolved coupling of an ICP antenna to a plasma.

Here, “input signal” may generally refer to a signal of a desired frequency provided by a signal source.

Here, “metal-oxide varistor” or “MOV” may generally refer to an electronic component with a resistance that varies with an applied voltage. In at least one implementation, at a low voltage, the MOV has a high resistance which decreases as the voltage is raised. The MOV is also known as a voltage-dependent resistor.

Here, “diode” may generally refer to a two-terminal electronic component that conducts current primarily in one direction. In at least one implementation, diode has a low (ideally zero) resistance in one direction, and a high (ideally infinite) resistance in the other direction.

Here, “low frequency signals” or “low frequency components” may generally refer to signals having a low frequency range (e.g., between 0 Hz and 0.5 kHz), and “high frequency signals” or “high frequency components” may generally refers to signals having a high frequency range (e.g., above 0.5 MHz).

Here, “ion” may generally refer to a charged atom or molecule. In at least one implementation, an ion may be a gaseous atom or molecule that loses or gains an electron in a plasma.

Here, “high impedance” may generally refer to a node in a circuit that allows substantially zero current or relatively small amount of current to flow through that node upon voltage applied at that node. In at least one implementation, a node which is not driven to any logic level is a high impedance node.

Here, “low impedance”, relative to high impedance may generally refer to a node in a circuit that allows a relatively high amount of current to flow through upon voltage applied at that node.

Here, “surge protection circuit” may generally refer to a circuit which protects a system from a voltage spike or a surge. In at least one implementation, in response to a voltage spike, “surge protection circuit” may provide a short circuit connection between the system and a common potential (e.g., ground), and thus protect the system from the voltage spike.

Here, “over-voltage detection circuit” may generally refer to a circuit which indicates an over-voltage condition if a voltage at a node or a terminal exceeds an over-voltage limit (e.g., 1000V, 2000V, or 3000V).

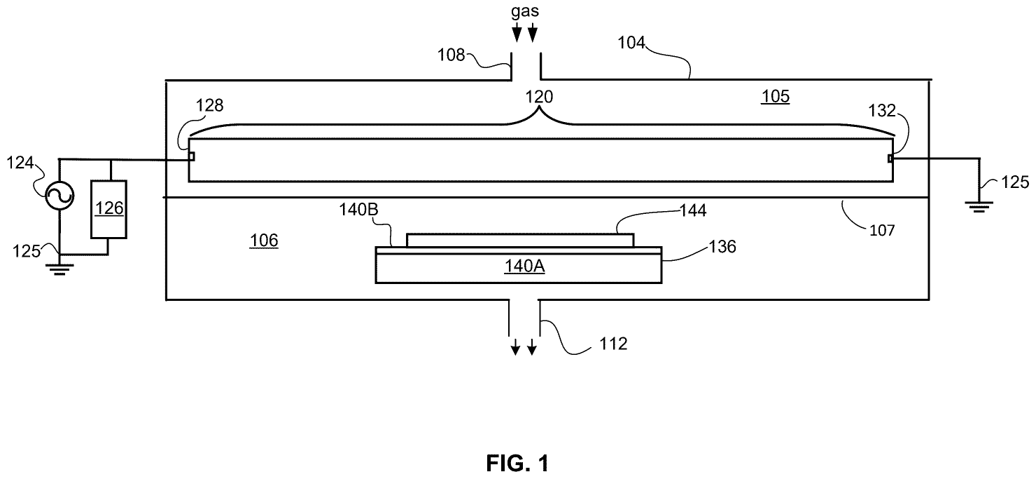

FIG. 1 illustrates system 100, in accordance with at least one implementation. In at least one implementation, system 100 includes chamber 104, first region 105, second region 106, separation window 107, intake valve 108, exhaust valve 112, transmission line 120, signal source 124, surge protection circuit 126, input terminal 128, termination node 132, electrostatic chuck 136, electrode plate 140A, insulator 140B, and wafer 144.

Chamber 104 is configured to generate and contain plasma. In at least one implementation, chamber 104 may be partitioned into first region 105 and second region 106 by separation window 107. In at least one implementation, separation window 107 may be constructed with a non-electrically conductive material (e.g., dielectric), such as polymer, ceramic, glass, wood, etc. In at least one implementation, first region 105 is also referred to as an antenna region or a transmission line region. Second region 106 is also referred to as a vacuum region or a plasma region.

In at least one implementation, chamber 104 may include intake valve 108 through which gas is pumped into the chamber and may include exhaust valve 112 for removal of the gas. In at least one implementation, gas may be generally contained in second region 106. In at least one implementation, although chamber 104 is shown as having a rectangular shape, chamber 104 can be built having other suitable shapes such as, but not limited to, a dome shape.

In at least one implementation, system 100 includes transmission line 120 in first region 105 (also known as a utility region). In at least one implementation, transmission line 120 may have an equivalent resistance of around 50 ohms. In at least one implementation, signal source 124 is electrically connected between input terminal 128 and common potential 125 (e.g., ground). In at least one implementation, signal source 124 feeds a signal to transmission line 120. In at least one implementation, signal source 124 can be a signal generator configured to generate a DC voltage or an AC voltage of a desired frequency.

In at least one implementation, transmission line 120 has termination node 132 which can be coupled to common potential 125 (e.g., ground). In at least one implementation, termination node 132 may be capacitively coupled to ground.

In at least one implementation, system 100 includes electrostatic chuck 136 in second region 106 (also known as a plasma region). In at least one implementation, electrostatic chuck 136 may include electrode plate 140A and insulator 140B disposed on electrode plate 140A. In at least one implementation, insulator 140B may include dielectric materials including ceramics such as alumina (Al₂O₃), silicon dioxide (SiO₂), silicon nitride (Si₃N₄), and/or sapphire. In at least one implementation, a wafer or semiconductor substrate 144 may be placed on electrostatic chuck 136.

In at least one implementation, in operation, system 100 controls plasma-assisted deposition, cleaning or etching on substrate 144 by spatially modulating ion energy distributions within a plasma created within plasma chamber 104. In at least one implementation, by changing electrical parameters such as the frequency and voltage of the applied signal that is fed into transmission line 120, system 100 controls the spatial distribution and ion energy of the plasma. In at least one implementation, system 100 is operable to spatially control plasma processes such as Plasma Enhanced Chemical Vapor Deposition (PECVD) or Plasma Enhanced Atomic Layer Deposition (PEALD), as well as plasma cleaning and ion etch processes such as reactive ion etching, on substrate 144.

Although transmission line 120 is illustrated as having a linear structure, transmission line 120 can have other suitable shapes. In at least one implementation, transmission line 120 can be wound into a coil such as a pancake-shaped coil.

In at least one implementation, surge protection circuit 126 may be coupled between input terminal 128 and common potential 125 (e.g., ground). In at least one implementation, a voltage spike or surge may occur in chamber 104 due to “arcing” during plasma processing or due to a change in load (e.g., semiconductor wafer or substrate) 144. In at least one implementation, voltage spike or surge is a transient event, typically lasting 1 to 30 microseconds, may reach, for example, 1000V, 2000V, or 3000V. The voltage spike or surge may be reflected at input terminal 128, thus coupling signal source 124 to the voltage spike or surge. In at least one implementation, as a result, signal source 124 may be damaged. In various implementations, if a voltage level at input terminal 128 exceeds an over-voltage limit (e.g., 1000V, 2000V or 3000V) due to a voltage spike or surge, surge protection circuit 126 couples input terminal 128 to common potential 125. In at least one implementation, surge protection circuit 126 diverts a resulting surge current to common potential 125 (e.g., ground), thereby protecting signal source 124 from being damaged.

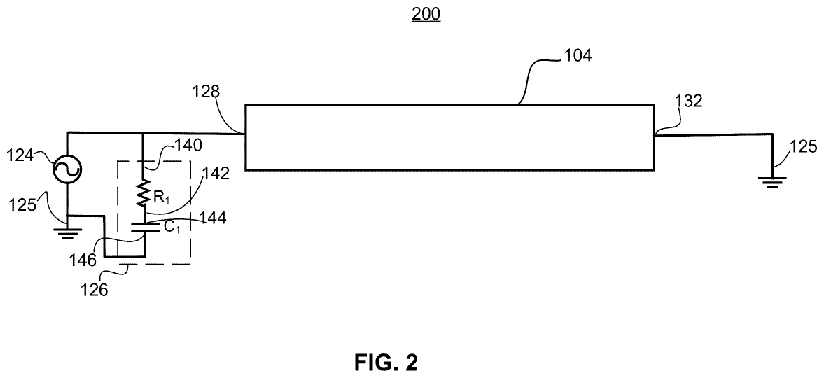

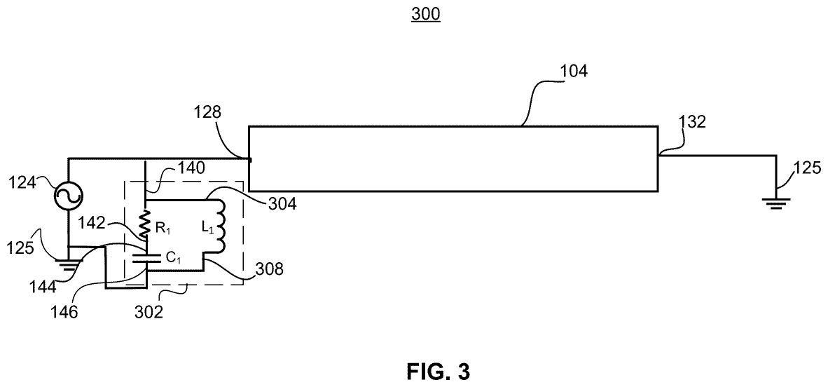

FIG. 2 illustrates system 200 of an example implementation that includes an implementation of surge protection circuit 126. In at least one implementation, system 200 includes chamber 104, signal source 124, surge protection circuit 126, input terminal 128, and termination node 132.

In at least one implementation, surge protection circuit 126 includes resistor R1 coupled in series with capacitor C1. In at least one implementation, resistor R1 includes first terminal 140 coupled to input terminal 128 and includes second terminal 142. In at least one implementation, capacitor C1 includes first terminal 144 coupled to second terminal 142 of R1 and includes second terminal 146 coupled to common potential 125 (e.g., ground). In at least one implementation, capacitor C1 may be implemented as a metal-oxide varistor (MOV), in accordance with some implementations. In at least one implementation, MOV is an electronic component with a resistance that varies with the applied voltage. In at least one implementation, at a low voltage, the MOV may have a high resistance (e.g., 1000 ohms, 2000 ohms) which decreases as the voltage is raised. In at least one implementation, MOV is also known as a voltage-dependent resistor.

In at least one implementation, since the MOV may have a high resistance at a low voltage, capacitor C1 acts as an open circuit at a high voltage. In at least one implementation, at a low voltage surge protection circuit 126 does not affect the operation of system 100. In at least one implementation, at a high voltage, the MOV has a very low resistance, and thus capacitor C1 as a short circuit. In at least one implementation, if a voltage level at input terminal 128 exceeds an over-voltage limit (e.g., 1000V, 2000V, or 3000V) due to a voltage spike, surge protection circuit 126 activates. In at least one implementation, surge protection circuit 126 couples input terminal 128 to common potential 125 (e.g., ground) to divert a transient surge current resulting from the voltage spike to common potential 125 (e.g., ground). In at least one implementation, surge protection circuit 126 prevents signal source 124 from being damaged. In some example implementations, surge protection circuit 126 provides a fast response and can couple input terminal 128 to common potential 125 (e.g., ground) within a few nano seconds of the occurrence of a voltage spike.

In at least one implementation, at an operating frequency (e.g., 400 kHz), capacitor C1 may have a high impedance. In at least one implementation, if “arcing” in chamber 104 generates a high frequency transient surge current (e.g., 1 MHz or 5 MHz), the transient current may appear at input terminal 128. In at least one implementation, because at a high frequency, capacitor C1 has a very low impedance (e.g., near zero), the transient surge current may be diverted to common potential 125 (e.g., ground) via surge protection circuit 126, in accordance with various implementations.

In some example implementations, capacitor C1 may have a capacitance of around 20 nano-farads or 30 nano-farads at 500V (e.g., operating voltage), and resistor R1 may have a resistance of around 2.7 ohms.

FIG. 3 illustrates system 300 of an example implementation in which a surge protection circuit 302 is implemented with a passive RLC circuit, in accordance with at least one implementation. In at least one implementation, system 300 includes chamber 104, signal source 124, surge protection circuit 302, input terminal 128, and termination node 132.

In at least one implementation, surge protection circuit 302 includes inductor L1 (e.g., around 143 uH) coupled in parallel with resistor R1 (e.g., around 2.77 ohms) and capacitor C1. In at least one implementation, capacitor C1 may be implemented as an MOV. Inductor L1 includes first terminal 304 coupled to first terminal 142 of resistor R1, and second terminal 308 coupled to second terminal 144 of capacitor C1. In at least one implementation, inductor L1, capacitor C1, and resistor R1 form the passive RLC circuit in which oscillation occurs at a resonant frequency fc, and stored energy may be exchanged between inductor L1 and capacitor C1. In at least one implementation, at resonance, the impedance of the passive RLC circuit may be equal to R1.

In at least one implementation, because the impedance of C1 may be dependent on the applied voltage, by choosing the inductance value of L1, the passive RLC circuit can be tuned to resonate at a specific fc. In at least one implementation, if the normal operating frequency of system 300 is around 400 kHz, the passive RLC circuit can be tuned to resonate at a higher frequency (e.g., 1 MHz or 5 MHz). In at least one implementation, resistor R1 increases the decay of the oscillation, which is known as damping.

In at least one implementation, due to “arcing” in chamber 104, a transient voltage spike or surge may be reflected at input terminal 128. The transient voltage spike may have a high frequency (e.g., 1 MHz or 5 MHz). In at least one implementation, inductance of L1 may be chosen so that the passive RLC circuit resonates at, for example, around 1 MHz or 5 MHz. Thus, a transient surge current may oscillate in the passive RLC circuit. In at least one implementation, effect of this is that the transient surge current may be prevented from flowing into signal source 124, thus preventing signal source 124 from being damaged. In an example implementation, the inductor L1 is a variable inductor (e.g., inductance may be adjusted).

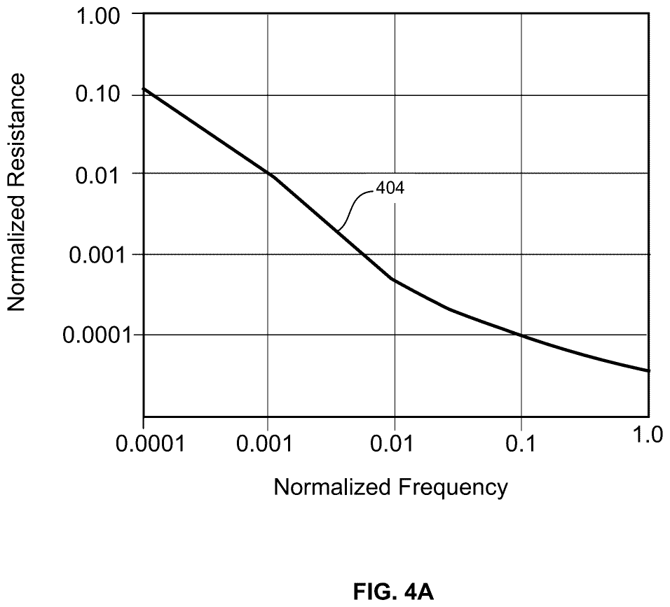

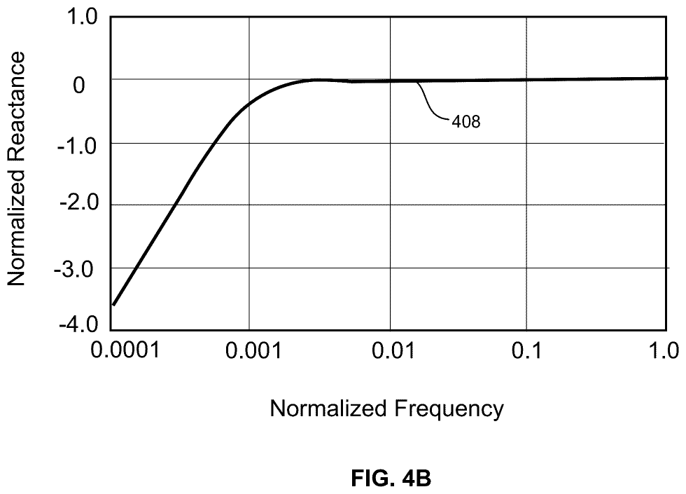

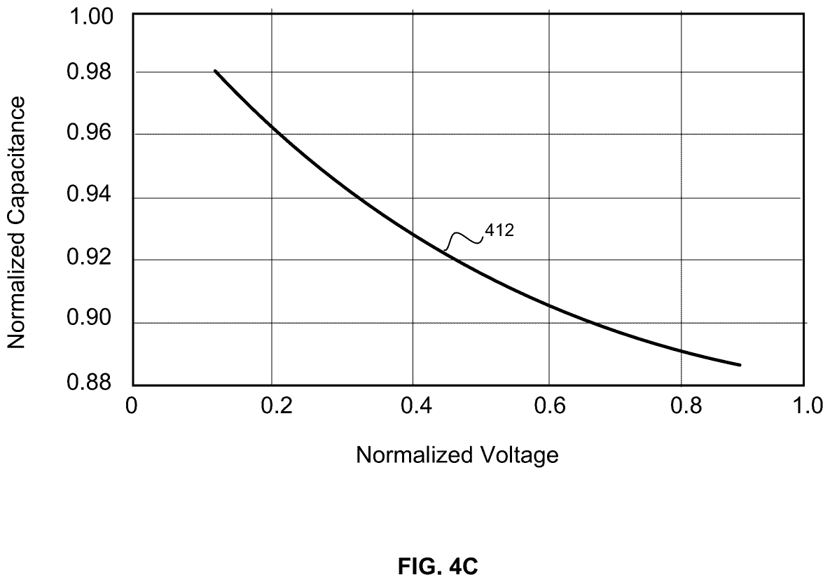

FIG. 4A illustrates plot 404 of a resistance of a metal-oxide varistor (MOV) used in surge protection circuit 126 at lower frequencies, in accordance with at least one implementation. In FIG. 4A, the x-axis represents a frequency normalized between 0.0001 and 1.0 while the y-axis represents a resistance normalized between 0.0 and 1.0. At around 0.0001 arbitrary units (a.u.) (e.g., 100 Hz), the MOV has a resistance of around 0.1 a.u. (e.g., 1000 ohms). At around 0.0004 a.u. (e.g., 400 kHz), the MOV has a resistance of around 0.2 a.u. (e.g., 2 ohms). At low frequencies, due to the high resistance (e.g., 1000 ohms) of the MOV, power supplied by signal source 124 flows into transmission line 120. FIG. 4B illustrates a plot 408 of a reactance of the MOV at lower frequencies. The x-axis represents a frequency normalized between 0.0001 and 1.0 while the y-axis represents a reactance normalized between −4.0 and 1.0. At around 0.004 a.u. (e.g., 400 kHz), the MOV has a reactance of around −2.0 a.u. (e.g., −400 j), and at around 0.1 a.u. (e.g., 10 MHz), the MOV has a reactance at near 0.

FIG. 4C illustrates plot 412 of a capacitance of the MOV as a function of a voltage at around 400 kHz, in accordance with at least one implementation. The x-axis represents a voltage normalized between 0 and 1.0 while the y-axis represents a capacitance normalized between 0.88 and 1.0. At around 0.4 a.u. (e.g., 100V), the MOV has a capacitance of around 0.93 a.u. (e.g., 0.93 nano-farads), and at around 0.8 a.u. (e.g., 200 V), the MOV has a capacitance of around 0.88 a.u. (e.g., 0.88 nano-farads).

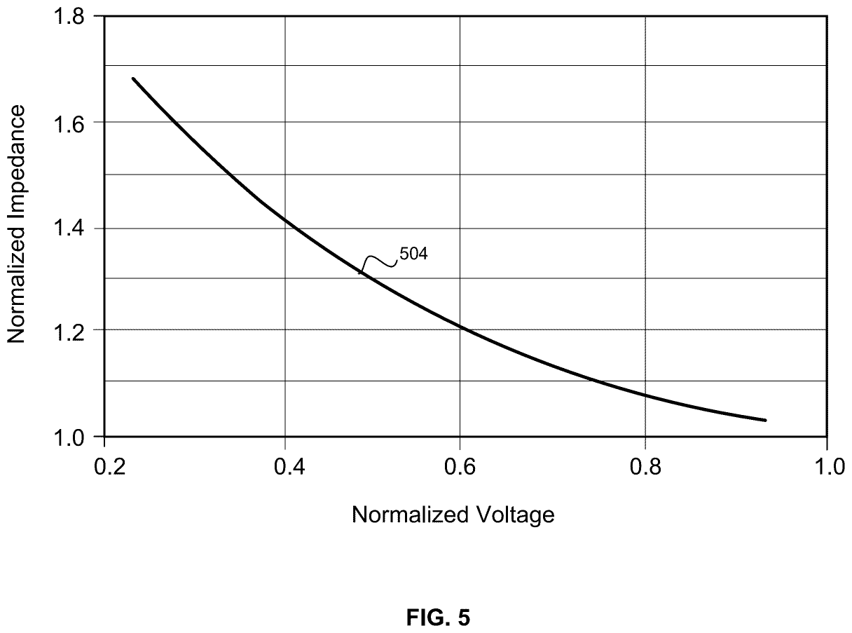

FIG. 5 illustrates plot 504 of a resistance of surge protection circuit 126 as a function of a voltage, in accordance with at least one implementation. In FIG. 5, the x-axis represents the voltage normalized between 0.2 and 1.0, and the y-axis represents the voltage normalized between 1.0 and 1.8. At around 0.37 a.u. (e.g., 100V), surge protection circuit 126 has a resistance of around 1.45 a.u. (e.g., 2800 ohms), and at around 0.8 a.u. (e.g., 210V) surge protection circuit 126 has a resistance of around 1.04 a.u. (e.g., 2100 ohms).

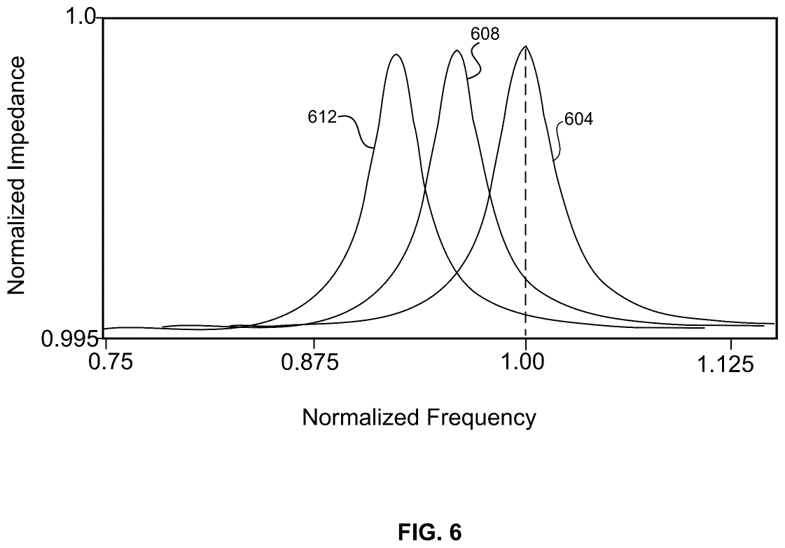

FIG. 6 illustrates plots 604, 608, and 612 of an impedance of surge protection circuit 126 as a function of a frequency as a capacitance of an MOV varies, in accordance with at least one implementation. Plot 604 shows the impedance when the MOV is around 1.1 nano-farads, plot 608 shows the impedance when the MOV is around 1.2 nano-farads and plot 612 shows the impedance when the MOV is around 1.3 nano-farads. The x-axis represents the frequency normalized between 0.7 and 1.125, and the y-axis represents the impedance normalized between 49.75 and 49.98. When the MOV is 1.1 nano-farads, at around 1.0 a.u. (e.g., 400 kHz), surge protection circuit 126 has an impedance of around 49.9 ohms. In at least one implementation, impedance drops rapidly at higher or lower frequencies. When the MOV is 1.2 nano-farads, at around 0.93 a.u. (e.g., 385 kHz), surge protection circuit 126 has an impedance of around 49.9 ohms. In at least one implementation, impedance drops rapidly at higher or lower frequencies. When the MOV is 1.3 nano-farads, at around 0.88 a.u. (e.g., 365 kHz), surge protection circuit 126 has an impedance of around 49.9 ohms. The impedance drops rapidly at higher or lower frequencies. Thus, as the capacitance of the MOV increase, the MOV exhibits peak impedance at a lower frequency.

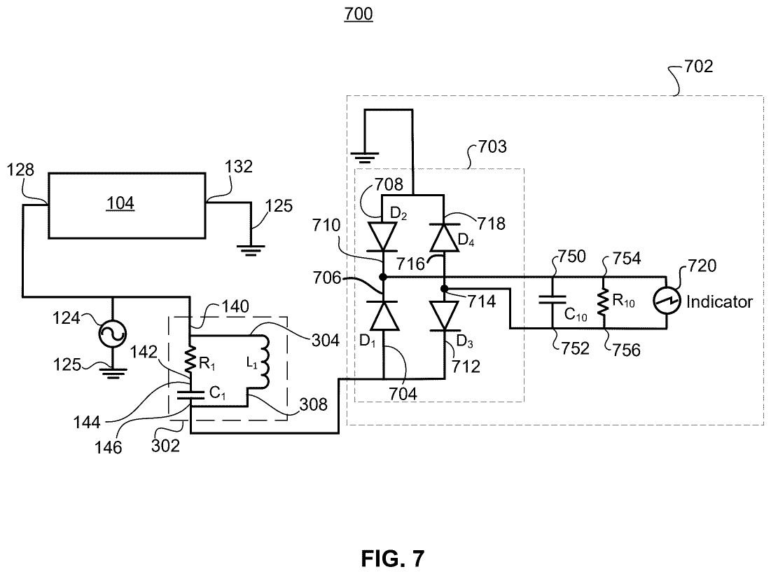

FIG. 7 illustrates system 700, in accordance with at least one implementation. System 700 is similar to system 300 except that system 700 includes over-voltage detection circuit 702. In at least one implementation, system 700 includes chamber 104, signal source 124, surge protection circuit 302, input terminal 128, termination node 132, diodes D1-D4, capacitor C10, resistor R10 and voltage level indicator 720.

In at least one implementation, diodes D1-D4 form rectifier 703 which may rectify a voltage spike or surge at input terminal 128 and may provide a conduction path to charge capacitor C10. In at least one implementation, diode D1 includes anode 704 coupled to second terminal 146 of capacitor C1 and includes cathode 706. Diode D2 includes anode 708 coupled to common potential 125 and includes cathode 710 coupled to anode 706. In at least one implementation, diode D3 includes cathode 712 coupled to anode 704 and includes anode 714. Diode D4 includes anode 716 coupled to anode 714 and includes cathode 718 coupled to common potential 125. In at least one implementation, capacitor C10 (e.g., around 0.033 micro-farads) includes first terminal 750 coupled to cathodes 706 and 710 and includes second terminal 752 coupled to anodes 714 and 716. In at least one implementation, resistor R10 (e.g., around 2000 ohms) includes first terminal 754 coupled to first terminal 750 of capacitor C10 and includes second terminal 756 coupled to second terminal 752 of resistor R10. In at least one implementation, voltage level indicator 720 is coupled in parallel with capacitor C10 and resistor R10.

In at least one implementation, responsive to a voltage spike at input terminal 128, diodes D1 and D3 may be forward biased. In at least one implementation, a transient surge current due to the voltage spike may conduct through D1 and D3 and charge capacitor C10. If the voltage across capacitor C10 exceeds an over-voltage limit (e.g., 1000V, 2000V, or 3000V), voltage level indicator 720 may indicate an over-voltage condition (e.g., LED, alarm). Capacitor C10 is discharged through R10 and diodes D4 and D3. In at least one implementation, diodes D1-D10 are power semiconductor devices which are rated to operate at a very high voltage (e.g., 4000V).

In at least one implementation, voltage level indicator 720 may be coupled to resistor R10 and capacitor C10 via an interface such as, for example, an optical fiber interface, a digital interface or an analog interface. In at least one implementation, over-voltage detection circuit 702 may be coupled via a communication link (e.g., Internet, wired or wireless communication link) to a monitor or a server (not shown in FIG. 7). In at least one implementation, monitor or the server may be located remotely from over-voltage detection circuit 702. In at least one implementation, monitor or the server may be located on the cloud and may be connected to over-voltage detection circuit 702 via a communication link. In at least one implementation, in response to a voltage spike which may trigger surge protection circuit 302 to couple input terminal 128 to common potential 125 (e.g., ground), a message or a notification may be transmitted to the monitor indicating a status (e.g., surge protection circuit 302 has triggered). In at least one implementation, a user may be able to monitor the status of system 700 remotely.

Besides what is described herein, various modifications may be made to the disclosed implementations and implementations thereof without departing from their scope. Therefore, illustrations of implementations herein should be construed as examples only, and not restrictive to the scope of the present disclosure. The scope of the invention should be measured solely by reference to the claims that follow.

Following examples are provided that illustrate the various implementations. The examples can be combined with other examples. As such, various implementations can be combined with other implementations without changing the scope of the invention.

Example 1: A system comprising: a chamber configured to produce and contain a plasma; a transmission line positioned in the chamber, the transmission line including a transmission line input and an output, wherein the output is coupled to a common potential; a signal source coupled to the transmission line input, wherein the signal source feeds an input signal to the transmission line; and a metal oxide varistor (MOV) coupled between the transmission line input and the common potential, wherein an impedance of the MOV is inversely related to a voltage level at the transmission line input.

Example 2: The system of example 1, wherein the MOV has a high impedance if the voltage level at the transmission line input is greater than an over-voltage limit, and wherein the MOV has a low impedance if the voltage at the transmission line input is less than the over-voltage limit.

Example 3: The system of example 1, wherein the MOV is operable to provide a short circuit path between the transmission line input and the common potential if the voltage level at the transmission line input is greater than an over-voltage limit.

Example 4: The system of example 1, wherein the chamber comprises first and second regions, and wherein the plasma is contained in the first region, and wherein the transmission line is positioned in the second region.

Example 5: A system comprising: a chamber configured to produce and contain a plasma; a transmission line positioned in the chamber, the transmission line including a transmission line input and an output, wherein the output is coupled to a common potential; a signal source coupled to the transmission line input, wherein the signal source feeds an input signal to the transmission line; a resistor including a first terminal and a second terminal, wherein the first terminal of the resistor is coupled to the transmission line input; and a metal-oxide varistor (MOV) including a first terminal and a second terminal, wherein the first terminal of the MOV is coupled to the second terminal of the resistor, and wherein the second terminal of the MOV is coupled to the common potential.

Example 6: The system of example 5, wherein an impedance of the MOV is inversely related to a voltage level at the transmission line input.

Example 7: The system of example 5, wherein the MOV has a high impedance if a voltage level at the transmission line input is greater than an over-voltage limit, wherein the MOV has a low impedance if the voltage level at the transmission line input is less than the over-voltage limit.

Example 8: The system of example 5, wherein the MOV is operable to provide a short circuit path between the transmission line input and the common potential if a voltage level at the transmission line input is greater than an over-voltage limit.

Example 9: The system of example 5, wherein the chamber comprises first and second regions, and wherein the plasma is contained in the first region and the transmission line is positioned in the second region.

Example 10: A system comprising: a chamber configured to produce and contain a plasma; a transmission line positioned in the chamber, the transmission line including a transmission line input and an output, wherein the output is coupled to a common potential; a signal source coupled to the transmission line input, wherein the signal source feeds an input signal to the transmission line; a resistor including a first terminal and a second terminal, wherein the first terminal of the resistor is coupled to the transmission line input; a metal-oxide varistor (MOV) including a first terminal and a second terminal, wherein the first terminal of the MOV is coupled to the second terminal of the resistor, and wherein the second terminal of the MOV is coupled to the common potential; and an inductor including a first terminal and a second terminal, wherein the first terminal of the inductor is coupled to the transmission line input and the second terminal of the inductor is coupled to the common potential.

Example 11: The system of example 10, wherein an impedance of the MOV is inversely related to a voltage level at the transmission line input.

Example 12: The system of example 10, wherein the MOV has a high impedance if a voltage level at the transmission line input is greater than an over-voltage limit, and wherein the MOV has a low impedance if the voltage level at the transmission line input is less than the over-voltage limit.

Example 13: A system comprising: a chamber configured to produce and contain a plasma; a transmission line positioned in the chamber, the transmission line including a transmission line input and an output, wherein the output is coupled to a common potential; a signal source coupled to the transmission line input, wherein the signal source feeds an input signal to the transmission line; a resistor including a first terminal and a second terminal, wherein the first terminal of the resistor is coupled to the transmission line input; a metal-oxide varistor (MOV) including a first terminal and a second terminal, wherein the first terminal of the MOV is coupled to the second terminal of the MOV; an inductor including a first terminal and a second terminal, wherein the first terminal of the inductor is coupled to the transmission line input and the second terminal of the inductor is coupled to the second terminal of the MOV; and an over-voltage detection circuit including a first terminal coupled to the second terminal of the MOV and a second terminal coupled to the common potential.

Example 14: The system of example 13, wherein an impedance of the MOV is inversely related to a voltage level at the transmission line input.

Example 15: The system of example 13, wherein the MOV has a high impedance if a voltage level at the transmission line input is greater than an over-voltage limit.

Example 16: The system of example 13, wherein the MOV has a low impedance if a voltage level at the transmission line input is less than an over-voltage limit.

Example 17: The system of example 13, wherein the over-voltage detection circuit comprises a rectifier coupled between the second terminal of the MOV and the common potential.

Example 18: The system of example 17, wherein the over-voltage detection circuit comprises a capacitor coupled to the rectifier.

Example 19: The system of example 18, wherein the over-voltage detection circuit comprises a resistor coupled in parallel with the capacitor.

Example 20: The system of example 18, wherein the over-voltage detection circuit comprises a voltage level indicator coupled in parallel with the capacitor.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate implementation.

What is claimed is:

1. A system comprising:
a chamber configured to produce and contain a plasma;
a transmission line positioned in the chamber, the transmission line including a transmission line input and an output, wherein the output is coupled to a common potential;
a signal source coupled to the transmission line input, wherein the signal source feeds an input signal to the transmission line; and
a metal oxide varistor (MOV) coupled between the transmission line input and the common potential, wherein an impedance of the MOV is inversely related to a voltage level at the transmission line input.

2. The system of claim 1, wherein the MOV has a high impedance if the voltage level at the transmission line input is greater than an over-voltage limit, and wherein the MOV has a low impedance if the voltage at the transmission line input is less than the over-voltage limit.

3. The system of claim 1, wherein the MOV is operable to provide a short circuit path between the transmission line input and the common potential if a voltage level at the transmission line input is greater than an over-voltage limit.

4. The system of claim 1, wherein the chamber comprises first and second regions, and wherein the plasma is contained in the first region, and wherein the transmission line is positioned in the second region.

5. A system comprising:
a chamber configured to produce and contain a plasma;
a transmission line positioned in the chamber, the transmission line including a transmission line input and an output, wherein the output is coupled to a common potential;
a signal source coupled to the transmission line input, wherein the signal source feeds an input signal to the transmission line;
a resistor including a first terminal and a second terminal, wherein the first terminal of the resistor is coupled to the transmission line input; and
a metal-oxide varistor (MOV) including a first terminal and a second terminal, wherein the first terminal of the MOV is coupled to the second terminal of the resistor, and wherein the second terminal of the MOV is coupled to the common potential.

6. The system of claim 5, wherein an impedance of the MOV is inversely related to a voltage level at the transmission line input.

7. The system of claim 5, wherein the MOV has a high impedance if a voltage level at the transmission line input is greater than an over-voltage limit, wherein the MOV has a low impedance if the voltage level at the transmission line input is less than the over-voltage limit.

8. The system of claim 5, wherein the MOV is operable to provide a short circuit path between the transmission line input and the common potential if a voltage level at the transmission line input is greater than an over-voltage limit.

9. The system of claim 5, wherein the chamber comprises first and second regions, and wherein the plasma is contained in the first region and the transmission line is positioned in the second region.

10. A system comprising:
a chamber configured to produce and contain a plasma;
a transmission line positioned in the chamber, the transmission line including a transmission line input and an output, wherein the output is coupled to a common potential;
a signal source coupled to the transmission line input, wherein the signal source feeds an input signal to the transmission line;
a resistor including a first terminal and a second terminal, wherein the first terminal of the resistor is coupled to the transmission line input;
a metal-oxide varistor (MOV) including a first terminal and a second terminal, wherein the first terminal of the MOV is coupled to the second terminal of the resistor, and wherein the second terminal of the MOV is coupled to the common potential; and
an inductor including a first terminal and a second terminal, wherein the first terminal of the inductor is coupled to the transmission line input and the second terminal of the inductor is coupled to the common potential.

11. The system of claim 10, wherein an impedance of the MOV is inversely related to a voltage level at the transmission line input.

12. The system of claim 10, wherein the MOV has a high impedance if a voltage level at the transmission line input is greater than an over-voltage limit, and wherein the MOV has a low impedance if the voltage level at the transmission line input is less than the over-voltage limit.

13. A system comprising:
a chamber configured to produce and contain a plasma;
a transmission line positioned in the chamber, the transmission line including a transmission line input and an output, wherein the output is coupled to a common potential;
a signal source coupled to the transmission line input, wherein the signal source feeds an input signal to the transmission line;
a resistor including a first terminal and a second terminal, wherein the first terminal of the resistor is coupled to the transmission line input;
a metal-oxide varistor (MOV) including a first terminal and a second terminal, wherein the first terminal of the MOV is coupled to the second terminal of the MOV;
an inductor including a first terminal and a second terminal, wherein the first terminal of the inductor is coupled to the transmission line input and the second terminal of the inductor is coupled to the second terminal of the MOV; and
an over-voltage detection circuit including a first terminal coupled to the second terminal of the MOV and a second terminal coupled to the common potential.

14. The system of claim 13, wherein an impedance of the MOV is inversely related to a voltage level at the transmission line input.

15. The system of claim 13, wherein the MOV has a high impedance if a voltage level at the transmission line input is greater than an over-voltage limit.

16. The system of claim 13, wherein the MOV has a low impedance if a voltage level at the transmission line input is less than an over-voltage limit.

17. The system of claim 13, wherein the over-voltage detection circuit comprises a rectifier coupled between the second terminal of the MOV and the common potential.

18. The system of claim 17, wherein the over-voltage detection circuit comprises a capacitor coupled to the rectifier.

19. The system of claim 18, wherein the over-voltage detection circuit comprises a resistor coupled in parallel with the capacitor.

20. The system of claim 18, wherein the over-voltage detection circuit comprises a voltage level indicator coupled in parallel with the capacitor.
